(19) United States
(12) Patent Application Publication
(10) Pub. No.: US 2021/0116423 A1
(43) Pub. Date: Apr. 22, 2021

(54) PARTICLE FILTER MONITORING

(71) Applicant: Eaton Intelligent Power Limited, Dublin 4 (IE)

(72) Inventor: Jouko Paavilainen, Lohja (FI)

(21) Appl. No.: 17/047,702

(22) PCT Filed: Apr. 10, 2019
(86) PCT No.: PCT/EP2019/059076

§ 371 Date: Oct. 15, 2020

(30) Foreign Application Priority Data
Apr. 16, 2018 (GB) 1806149.9

(51) Int. Cl. G01N 29/50; G01N 29/12; G01N 29/14; G01N 29/32; G01N 29/44; G01N 29/46; B01D 46/00; H02J 9/06; H05K 7/20

(52) U.S. Cl. CPC G01N 29/50; G01N 29/12; G01N 29/14; G01N 29/32; G01N 29/4427; B01D 2279/45; B01D 46/0086; H02J 9/06; H05K 7/20136; G01N 2291/0258; B01D 2273/24; G01N 29/46

(57) ABSTRACT

A method for detecting particle filter cleanliness includes receiving calibration data for a particle filter. The calibration data represents an acoustic spectrum. The method further includes receiving operational acoustic data from a sensor located in a system comprising a fan and the particle filter, deriving a second acoustic spectrum from the operational acoustic data, comparing at least part of the acoustic spectrum with a corresponding part of the second acoustic spectrum, determining a frequency shift between the acoustic spectrum and the second acoustic spectrum based on the comparing step, and providing an output based on the frequency shift.

### CROSS-REFERENCE TO PRIOR APPLICATIONS

This application is a U.S. National Phase application under 35 U.S.C. § 371 of International Application No. PCT/EP2019/059076, filed on Apr. 10, 2019, and claims benefit to British Patent Application No. GB 1806149.9, filed on Apr. 16, 2018. The International Application was published in English on Oct. 24, 2019 as WO 2019/201700 under PCT Article 21(2).

### FIELD

This relates to a particle filter monitoring. In particular, this relates to a method for monitoring or detecting particle filter cleanliness and a system for performing said method.

### BACKGROUND

Many electronic and electrical devices require cooling to prevent the devices overheating. Typically, a flow of cooling fluid (i.e. a liquid or a gas) is arranged to flow over or through the devices to provide this cooling. The cooling flow of fluid is usually filtered, by means of a particle filter, to prevent foreign material from entering the electronic or electrical devices. However, for efficient cooling to occur, it is important that the flow of cooling fluid is not obstructed by a dirty filter (i.e. that the particle filter is not overly clogged with particles).

Particle filters are therefore typically cleaned or replaced at certain, predetermined, intervals. This approach can lead to filters being replaced too soon, or too late, which can lead to unnecessary costs being incurred (and, in the latter case, possibly affecting the lifetime of the electrical device). The timing of particle filter replacement is of particular importance in applications such as the cooling of uninterruptible power supply (UPS) devices; since UPS devices can be located on ships, or in military facilities, for example, it may be months before the particle filters of a UPS device can be serviced. It is therefore desirable to be able to monitor filter cleanliness so as to provide sufficient indication of the state of particle filter cleanliness, thereby allowing particle filters to be serviced or replaced when appropriate. In this way, service costs can be reduced and the lifetime of the electrical device prolonged.

Known approaches for monitoring particle filter cleanliness include monitoring a change in pressure across the filter as the filter cleanliness changes (the dirtier the filter, the greater the pressure drop across the filter), but this approach is complex and requires expensive and bulky monitoring systems. Moreover, pressure measurements are difficult to perform if the fluid flow is turbulent, as is typical near fans and other mechanical structures placed in the path of the fluid flow to aid cooling of the electrical device. A simpler and cheaper method of monitoring filter cleanliness is therefore required.

U.S. Pat. No. 6,964,694 B2 discloses monitoring a diesel particulate filter using acoustic sensing; pressure monitoring is not suitable for such an application because the hot diesel exhaust can cause burn-through of the particulate filter, which manifests itself in a significant lowering in the pressure drop across the filter. This low pressure drop can be incorrectly interpreted as a clean filter. U.S. Pat. No. 6,964,694 employs complex analysis to determine an acoustical transfer function for the frequency in order to obtain filter information. A simpler and cheaper method of monitoring filter cleanliness is therefore required.

DE102016207208 discloses determining the state of an air duct of an air conditioning device, in which a noise representative of the state of the air duct is recorded and analyzed by means of a microphone positioned in the air duct, the state of the air duct being determined on the basis of the analysis result. A spectral analysis of the recorded noise is performed.

US 2005/0247131 A1 discloses device for determining the state, in particular the permeability, of a particle filter. The device has an acoustic source for transmitting an acoustic signal toward the particle filter and has an acoustic receiver for receiving the acoustic signal that has been changed by the particle filter. The acoustic signal travels through the filter structure, which reduces its intensity and shifts its phase.

### SUMMARY

In an embodiment, the present invention provides a method of detecting particle filter cleanliness, the method comprising: receiving calibration data for a particle filter, the calibration data representing an acoustic spectrum; receiving operational acoustic data from a sensor located in a system comprising a fan and the particle filter; deriving a second acoustic spectrum from the operational acoustic data; comparing at least part of the acoustic spectrum with a corresponding part of the second acoustic spectrum; determining a frequency shift between the acoustic spectrum and the second acoustic spectrum based on the comparing; and providing an output based on the frequency shift.

### BRIEF DESCRIPTION OF THE DRAWINGS

The present invention will be described in even greater detail below based on the exemplary figures. The invention is not limited to the exemplary embodiments. Other features and advantages of various embodiments of the present invention will become apparent by reading the following detailed description with reference to the attached drawings which illustrate the following:

FIG. 1 shows a schematic diagram of a filter cleanliness monitoring system;

FIGS. 2A and 2B illustrate the principles of spectral analysis and the shift in frequency of spectral peaks due to a dirty particle filter as compared to a clean particle filter;

FIG. 3 outlines calibration steps for a clean filter for use in determining particle filter cleanliness; and

FIG. 4 outlines steps for determining particle filter cleanliness in accordance with the first aspect, with some optional features provided to illustrated the specific, exemplary, implementation of the method of the second aspect.

### DETAILED DESCRIPTION

In a first aspect, a method is provided as defined herein. In a second aspect, an example implementation of the method of the first aspect is provided herein, with optional features also described herein. In a third aspect, an apparatus arranged to perform the methods of the first and second aspects is provided.

In the following description, a method of detecting particle filter cleanliness is provided. The method comprises: receiving calibration data for a particle filter, the calibration data representing an acoustic spectrum; receiving operational acoustic data from a sensor located in a system comprising a fan and the particle filter; deriving a second acoustic spectrum from the operational acoustic data; comparing at least part of the acoustic spectrum with a corresponding part of the second acoustic spectrum; determining a difference between the acoustic spectrum and the second acoustic spectrum based on the comparing; and providing an output based on said difference.

In the following description, an example implementation of the above method for determining particle filter cleanliness is described. The example method comprises: receiving base acoustic data from a sensor located in a system comprising a fan and a particle filter, the base acoustic data representative of a clean particle filter; performing spectral analysis on the base acoustic data to determine one or more base spectral peaks representative of the base acoustic data; receiving operational acoustic data from the sensor; performing spectral analysis on the operational acoustic data to determine one or more operational spectral peaks, representative of the operational acoustic data, which correspond to the one or more base spectral peaks; comparing the one or more base spectral peaks to the one or more corresponding operational spectral peaks; determining a frequency and/or amplitude shift of the one or more operational spectral peaks relative to the one or more base spectral peaks; using the frequency shift to determine a measure of cleanliness of the particle filter; and providing an output based on the determined measure of cleanliness.

The use of spectral analysis in determining a difference, correlated with a measure of cleanliness of the particle filter, can provide a simple and cost-effective method which can utilise various noise sources from the system in the determination. The above described use of spectral peaks in the monitoring is a specific example of using spectral analysis to determine a correlation or difference between spectra. The difference, for example the frequency shift and/or amplitude shift (or amplitude variation), between the base and the operational spectral peaks can be determined regardless of the exact origin of the underlying acoustic emissions, i.e. whether the emissions are from the fluid itself or from the interaction of the fluid with other structures. As such, the method of the first aspect, and the example implementation of the second aspect, can provide a relatively robust approach, since noise does not necessarily need to be isolated or filtered before the method is performed.

Optionally, the system is for cooling an electrical device. In other words, base acoustic data is received from a sensor located in a system for cooling an electrical device, the system comprising the fan and the particle filter. Alternatively, calibration data is received for the particle filter which is intended for use in the system, which calibration data has been pre-determined. For example, the calibration data can be pre-determined prior to sale of a particle filter or with a prototype system, and then stored in such a manner that the calibration can be received for use in the monitoring of the particle filter. The state of particle filter cleanliness is of particular relevance in such applications, since cleanliness of the filter can affect how efficiently the electrical device is cooled, and thus can affect the lifetime of the electrical device. For efficient cooling a clean, or unclogged, filter is advantageous in order to maximise the flow of cooling fluid through the device.

Optionally, the acoustic data (base and/or operational) can be filtered such that only acoustic data within a predetermined frequency range is analysed. This can reduce computational load on the processor, thereby reducing the time required for the spectral analysis to be performed and reducing energy costs. The predetermined frequency range can be determined or set based on the application of the system. For example, an uninterruptible power supply (UPS) device may emit signals at certain, known, frequencies due to the operation of the device itself, which frequencies can be filtered prior to analysis of the acoustic emissions received from the sensor.

Optionally, to further conserve energy (of particular importance when the device in which the system is implemented is portable) the acoustic data (base and/or operational) is received from the sensor only periodically. Similarly, the calibration data may optionally be received only periodically. Optionally, the acoustic data is received at a frequency of at least once per month, optionally at a frequency of at least once per week. Optionally, the acoustic data is received daily or hourly. The frequency at which acoustic data is sensed, or received from the sensor, is advantageously predetermined based on the particular application, since particles will accumulate in the filter at different rates depending on the nature of the device in which the filter is used. The frequency at which calibration data is received may be dependent on other factors, for example, the expected lifetime of the device, or may be received only when a filter is changed, for example. For example, the calibration data may be received monthly, or yearly.

Advantageously, the difference in spectra is used to determine a measure of cleanliness of the particle filter. Using the difference to determine a measure of cleanliness may comprise determining the difference as a measure of cleanliness of the particle filter by way of calculating a correlation and/or mapping or comparing the spectra to each other. For example, when the difference can be considered to be a frequency and/or amplitude shift, said difference may be correlated or otherwise matched to a measure of cleanliness of the particle filter based on the correlation or mapping function by a calibration curve or a lookup table. This approach can enable different correlation or mapping functions to be employed depending on filter type and environmental parameters, as well as any other factors which may affect how the frequency shift corresponds to the measure of cleanliness.

In some embodiments, the calibration steps are performed independently of the monitoring of the particle filter, for example, before sale of the particle filter. These calibration steps can comprise: receiving base acoustic data from the sensor, the base acoustic data representative of a clean particle filter; and deriving the acoustic spectrum from the base acoustic data. Optionally, the calibration further comprises storing the calibration data representing the acoustic spectrum for subsequent use in the monitoring or detecting of particle filter cleanliness. As described above with reference to the second aspect, in some embodiments the calibration occurs at the same time as, or just before, detecting particle filter cleanliness.

In some embodiments, the first step in the method is detecting whether or not the particle filter has been changed. If the filter has been changed, calibration steps are performed and, if it is determined that a clean filter has been placed in the system, the mapping function may be modified based on characteristics of the determined base spectral peaks for said clean filter such that the correlation or mapping between the difference (for example the frequency and/or amplitude shift) and a measure of cleanliness is updated. In other embodiments, the calibration data which is stored may be adjusted or modified; in this arrangement, any mapping function or correlation function used to determine a measure of cleanliness may not be modified, since differences in the filter can be accounted for at the initial calibrations step, such that the determined difference in spectra may remain the same across different filters. This approach can enable dynamic calibration by recognising that frequency characteristics of one filter may not be identical to those of another filter, even where both filters are clean. If the filter is determined to be not clean (i.e. to be dirty), whether based on an automatic determination or a user input, the mapping function and/or calibration data is not modified. This can avoid any incorrect calibration of the system.

Advantageously, the output comprises an alert signal, such as an automated message or alarm, if the measure of cleanliness exceeds a predetermined threshold. The threshold can be determined in dependence on one or more environmental parameters, since such environmental parameters can affect the criticalness of failure of the particle filter. Optionally, the threshold is determined in dependence on the ambient temperature of the environment. Optionally, the output may be employed in real time monitoring. For example, a service person could use remote monitoring software to check a current status of one or more filters in several electrical devices. In such examples, the output may be a real time message (e.g. “Device A has 60% left of filter capacity but device B has only 12% left”).

In the following description, there is also provided an apparatus for performing the method of the first aspect (and that of the second, exemplary, aspect). The apparatus comprises a sensor for sensing acoustic emissions and a processor for receiving acoustic data representative of the acoustic emissions from the sensor. Optionally, the sensor is a microphone. The processor can be any suitable processor or microcontroller capable of performing or otherwise implementing the steps of the method of the first aspect.

Optionally, the apparatus forms part of an uninterruptible power supply (UPS) device. In other arrangements, the apparatus forms part of another electrical device comprising a fan and particle filter for cooling the device, the electric device being a personal computer, a rack mounted server system, or an inverter, for example.

In another aspect, a non-transient computer readable medium comprising stored instructions for implementing the above methods of the first and second aspects is provided. These instructions, when executed by a processor, cause the methods of the first and second aspects to be performed.

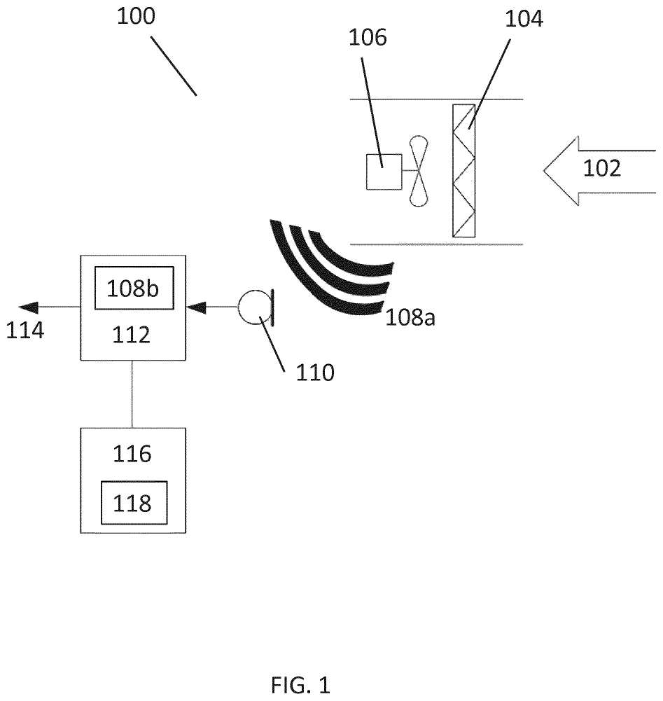

With reference to FIG. 1, a system 100 for monitoring particle filter cleanliness is described. A flow of fluid 102 is directed through a particle filter 104 and a fan 106 for use in cooling an electrical device. The fluid 102 in this example is air, but the fluid can be any other cooling gas or liquid, such as liquid nitrogen or water; when fluid 102 is a liquid, the fan 106 is a fan suitable for use in a liquid (for example, the fan could be suitable for use underwater). However, system 100 is also suitable for use in applications other than cooling, and fluid 100 can be any fluid suitable for such applications. It will be understood that the fan of the first and second aspects could be replaced with, or used within the system in addition to, a pump.

A sensor no is located in the system too and is arranged to sense acoustic emissions 108a. Sensor no can be, for example, a microphone arranged to record the acoustic emissions 108a, or any other suitable sensor for sensing acoustic emissions 108a. It is to be understood that sensor 110 can convert the acoustic emissions 108a into electrical signals for transmission to processor 112, or can transmit the acoustic emissions 108a to the processor 112 in any other suitable way. The data received at the processor 112 from sensor 100 is representative of the acoustic emissions 108a sensed by the sensor no. The following description refers to the information or data received, and processed, at the processor 112 as acoustic data 108b, to reflect the relationship between the acoustic data and the originating acoustic emissions 108a.

The acoustic emissions 108a can be noise generated by the fan 106, and the noise generated by the flow of fluid 102 through the fan 106, the particle filter 104, and any other structures located in the path of fluid 102. For example, the acoustic emissions 108 can comprise noise from the swirling or fluctuating flow of fluid 102 itself, as well as from the flow of fluid 102 through the particle filter 104. The noise can also include contributions from the vibrations of the components of the fan 106 (such as the fan plate and fan grill) due to both the operation of the fan 106 and the flow of fluid 102 through the fan 106. In short, the acoustic emissions 108a comprise noise from all structures in the path of fluid 102, or from only some structures. This noise varies depending on the speed of the fluid flow 102 through the filter, which is itself a function of the cleanliness of the filter 104—the dirtier (i.e. the more clogged) particle filter 104 is, the more the filter affects the speed of the fluid flowing through it (and hence the greater the variation in the frequency and amplitude characteristics of the acoustic emissions from fluid 102). As such, the acoustic emissions 108 can provide an indication of the state of filter cleanliness.

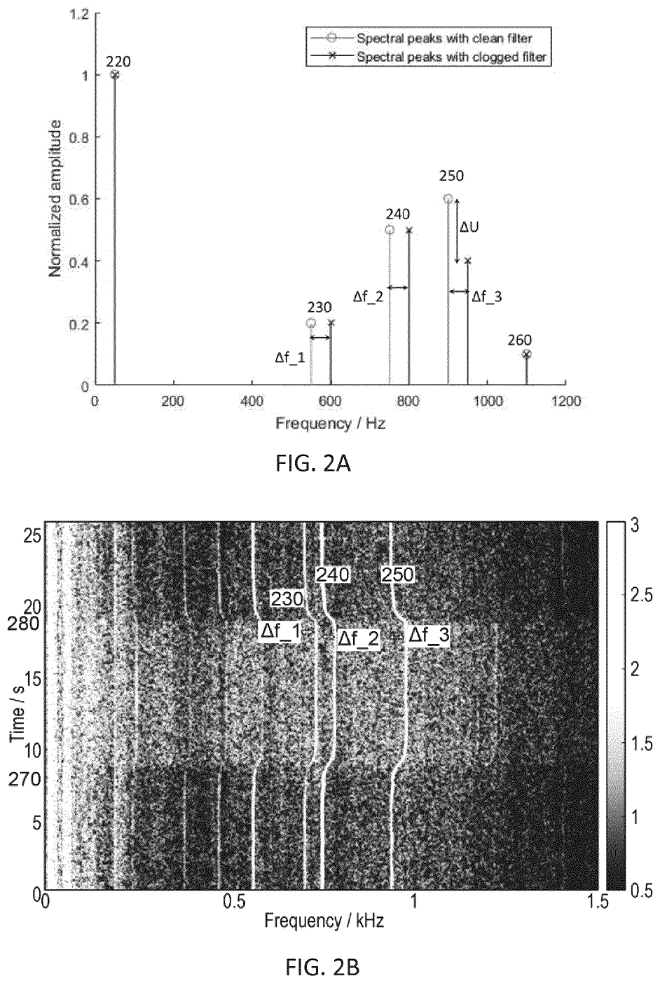

Acoustic data 108b, representative of the acoustic emissions 108a sensed by the sensor 110, are transmitted, via either a wireless or wired connection, to processor 112 for analysis. Spectral analysis of the acoustic data 108b received at the processor is performed to derive the acoustic spectrum from the acoustic data 108b; more specifically, in some examples the spectral analysis can be performed as described below with reference to FIGS. 2A and 2B. Based on the analysis, an output 114 can be provided.

A memory 116 is connected to processor 112. The processor 112 can be any suitable processing device (e.g., a processor core, a microprocessor, an ASIC, a FPGA, a controller, a microcontroller, etc.) and can be one processor or a plurality of processors that are operatively connected. The memory 116 can include one or more non-transitory computer-readable storage mediums, such as RAM, ROM, EEPROM, EPROM, flash memory devices, magnetic disks, etc., and combinations thereof. The memory 116 can store data and instructions 118, which instructions can be executed by the processor 112 to cause the processor 112 to perform operations.

Sensor 110 may be arranged to sense the acoustic emissions 108a periodically, for example hourly, daily, weekly, or monthly. Alternatively, the sensor 110 may continuously sense the acoustic emissions 108a, or may be arranged to sense the acoustic emissions automatically upon fulfilment of a predetermined condition or upon initiation by a user, for example. When the sensing is periodic, the sensor no is advantageously arranged to sense, or record, acoustic emissions 108a for a particular duration of time each period: for example, for a duration of less than a second, a few seconds (between 1 and 10 seconds), tens of seconds (between 10 seconds and 60 seconds), or minutes (1 minute or more).

By sensing acoustic emissions 108a periodically, and for a limited duration of time each period, the use of bandwidth in transmitting the corresponding acoustic data from the sensor to processor 112 can be minimised. Moreover, the processing power used by processor 112 in the subsequent analysis of the acoustic data 108b can be reduced. This effect can be particularly pronounced when the acoustic emissions 108a are sensed over short time periods, i.e. is a few seconds, optionally less than 1 second, optionally less than half a second. This arrangement may be beneficial in applications where the electrical device is portable, or battery operated, since taking only small samples of acoustic emissions 108a can reduce energy use in both gathering and analysing the data and can therefore save battery power.

Optionally, acoustic data 108b is filtered, either at the processor 112 or during the sensing of the acoustic emissions 108a at the sensor no, to reduce or remove noise from other components of the system. For example, some UPS devices emit noise at the switching frequency of the various switching devices, and other high frequency components of the UPS device (such as vibrating of inductors or other components due to the switching of the switching devices); in some examples, this frequency can be about 18 kHz, which can be removed from the acoustic data 108b before analysis. In this arrangement, an analog 2 kHz low-pass filter can be provided to filter out the high frequency components from the UPS. Similarly, very low frequency components of the acoustic emissions due to, for example, mains electricity, can be removed from the acoustic data 108b before analysis at the processor 112. For example, an analog or digital band-pass filter can be used.

FIG. 2A illustrates the general principles of an exemplary form of spectral analysis performed on the acoustic data 108b, and FIG. 2B represents experimental data which is illustrative of the principles outlined with respect to FIG. 2A.

In order to use operational acoustic noise to determine a measure of cleanliness of a particle filter, a base line of acoustic emissions for a clean particle filter is advantageously ascertained first; in other words, the system 100 can be calibrated. This calibration can occur independently of the method of monitoring the particle filter, i.e. in a factory setting, for example. In some embodiments, the base acoustic data is received from the sensor, the base acoustic data being representative of a clean particle filter, and an acoustic spectrum derived from the base acoustic spectrum. Calibration data representing the base acoustic spectrum may then be calculated or determined, and stored. The calibration data can then be received for use in the monitoring of particle filter cleanliness. In such an arrangement, the calibration data may not represent spectral peaks, as described below, but can be any other form of data representative of the base acoustic spectrum.

In some examples, the calibration process requires that base acoustic emissions representative of system too with a clean particle filter 104 are sensed by sensor 110 and passed to processor 112 as base acoustic data. Spectral analysis is then performed on the base acoustic data. Base acoustic emissions are an example of acoustic emissions 108a, and base acoustic data are an example of acoustic data 108b.

Spectral analysis of acoustic data provides an indication of how the power of the originating acoustic emissions is distributed across the different frequency components which make up that original emission, or signal. Where power is concentrated at certain frequencies, peaks can be discerned in the distribution at those particular frequencies. These peaks are referred to as ‘spectral peaks’ in the following description. Spectral analysis can comprise performing a Fourier transform on time series acoustic emissions and comparing spectra, for example by cross-correlation, or by any other suitable method.

In accordance with the exemplary implementation of the second aspect, and as can be seen in FIG. 2A, the base acoustic data can comprise base spectral peaks 220, 230, 240, 250, 260 (these peaks are represented by the grey lines and circles in FIG. 2A). Spectral peak 220 is a low frequency component, which can be indicative of background or environmental noise levels. In this example, base spectral peaks 230, 240 and 250 are selected for use in the subsequent detection of particle filter cleanliness. The spectral peaks selected can be, for example, the peaks with an amplitude above a predetermined threshold, or the peaks with the highest amplitude within a predefined frequency range. In this example, the frequency range considered is 500 Hz to 1 kHz, but any other suitable frequency range can be considered when selecting the base spectral peaks. The base spectral peaks 230, 240, 250 are used as a base level, or calibration, to ascertain the cleanliness of the particle filter 104 during operation of the system 100.

Once the calibration data is determined (for example, base spectral peaks are selected or calibration data measured)—which, as discussed above, may occur in a factory setting independently of the monitoring or in a separate calibration step—operational acoustic data can be sensed by sensor 110. Operational acoustic data are an example of acoustic data 108b, and represent the noise (or acoustic emissions 108a) from system 100 during ongoing operation of the system with a dirty (i.e. partially clogged) particle filter 104, or potentially with a completely clogged particle filter 104. Operational acoustic data therefore contains the noise generated by the fluid 102 and its interaction with the components of system 100, and the noise generated by the components of system 100 (i.e. the fan 106) themselves. As discussed above, the noise in the system 100 changes as the particle filter 104 becomes dirtier and flow of fluid 102 is obstructed (i.e. when the filter 104 is partially clogged with particles filtered from the fluid). This change in noise can be ascertained by analysing the operational acoustic data sensed by sensor 108 and comparing the results to those obtained for the base acoustic data or to the previously received calibration data.

In particular, operational acoustic data is sensed by sensor 110 and passed to processor 112. In some embodiments, an operational acoustic spectrum is derived from the operational acoustic data and some, or all, of the second acoustic spectrum is compared with a corresponding part of the base acoustic spectrum to determine a difference between the acoustic spectrum and the second acoustic spectrum based on the comparing. This difference can be determined using spectral analysis.

For example, one method to compare such spectra is by the mathematical function of correlation (e.g. cross-correlation, or a measure of a similarity of two series as a function of the displacement of one relative to the other). The correlation of the two spectra could be used as a proxy for a measure of cleanliness. For example, by correlating or otherwise comparing the operational acoustic spectrum with the base acoustic spectrum from a clean filter, and determining if the difference exceeds a certain threshold, or by correlating or otherwise comparing the operational acoustic spectrum with the base acoustic spectrum from a dirty filter, and determining if the spectra are similar or identical (i. e. differ by less than a certain threshold), and indicating of filter cleanliness can be obtained. Since such cross-correlation occurs in the frequency domain, this approach can take into account any peaks in the spectrum.

Another method is to perform spectral analysis on the operational acoustic data and directly determine the spectral peaks of the operational acoustic data for comparison to the calibration data. These operational peaks can be determined in the same way as the base peaks, described above. This method is described in more detail below, as an example. In particular, as can be seen in FIG. 2A, the operational acoustic data comprises spectral peaks 220, 230, 240, 250, 260 (these peaks are represented by the black lines and crosses in FIG. 2A, which in some cases overlap the grey lines/circles of the base spectral peaks, i.e. the peaks resulting from a clean filter).

It can be seen that the frequency of operational spectral peaks 230, 240 and 250 are shifted relative to the frequency of the base spectral peaks 230, 240, and 250 in this example, by a shift of Af₁, Af₂ and Af₃ respectively. Variations in the peak amplitude of the spectral peaks may also occur, as shown for operational spectral peak 250, where the amplitude variation relative to the base spectral peak is shown as AU. A shift or variation in peak amplitude can be measured by, for example, comparing the voltage of the base and operational data signals. The magnitude of this frequency (and in this case, amplitude) shift is dependent in part on the cleanliness of the particle filter 104 and, as such, can be used to determine a measure of cleanliness of the particle filter, as is described in more detail below.

The above described shift in frequency of spectral peaks 230, 240 and 250 is also illustrated in FIG. 2B, which shows a top view of a 3D spectrogram of experimental laboratory results. A spectrogram is a visual representation of the spectrum of frequencies (and amplitude) of acoustic emissions (and, correspondingly, acoustic data) as they vary with time. At the start of the experiment (time t=o), a single, clean filter is provided. At time point t=270, a second filter is added to the experimental set up to mimic a dirty, or partially clogged, filter. At time point t=28o, the second filter is removed and only the single, clean filter remains. The acoustic data sensed before time point 270, and after time point 280, is representative of the base acoustic data which would be received in a real system such as system 100 during the calibration process. The acoustic data received between time points 270 and 280 is representative of the operational acoustic data which would be received during operation of system too, where the particle filter 104 is not necessarily a clean filter.

As can be seen in FIG. 2B, the frequencies of the selected spectral peaks 230, 240 and 250 are shifted by Af Af₂ and Af₃, respectively, between the base acoustic data and the operational acoustic data. For spectral peak 250, this shift is about 50 Hz. This frequency shift can be used to determine a measure of cleanliness of the particle filter. Additionally or alternatively, a shift in the peak amplitude can be used to determine a measure of cleanliness of the particle filter. For example, a look up table or calibration curve can be used to match the determined frequency and/or amplitude shift to a measure of cleanliness of the particle filter. Such a calibration curve may be linear or non-linear. In other words, a mapping function is provided that maps the frequency and/or amplitude shift to the cleanliness of the particle filter, enabling a measure of cleanliness to be determined based on the frequency and/or amplitude shift.

Several mapping functions may be used, each mapping function corresponding to a different type of particle filter, for example. The different mapping functions may be stored remotely on a server and provided to the processor 212 upon request over a wireless or wired network. This arrangement allows the mapping functions to be globally updated when necessary. Alternatively, the mapping function(s) may be stored locally in memory 116 connected to processor 112, which arrangement obviates any issues with connectivity over a network which may be experienced due to the location of system 100. For example, mapping functions may be preloaded into the memory 116 associated with processor 112.

Optionally, system 100 may comprise one or more additional sensors for measuring environmental parameters, including, but not limited to, ambient temperature, air pressure (for example, atmospheric pressure) and relative humidity. Such environmental factors can impact on fluid density, which can affect the frequencies of the acoustic emissions 108a from system 100. As such, in some arrangements the mapping function(s) which map the determined difference (for example the frequency and/or amplitude shift of spectral peaks) to the cleanliness of the particle filter can be formulated to take into account one or more of the measured environmental parameters. In other arrangements, the calibration data can be modified or adjusted, either before or after being received within the method for detecting particle filter cleanliness, to take into account one or more of the measured environmental parameters.

The above described spectral analysis (e.g. determining and comparing the spectral peaks, or more generally comparing the acoustic spectra to determine a difference in said spectra) can be performed locally by processor 112, or remotely, depending on the application. The analysis can be performed on the acoustic data 108b in “real-time”, i.e. as the sensor 108 senses the acoustic emissions 108a. Alternatively, the acoustic data 108b can be stored in memory 116 and the analysis can be performed at a later point in time.

When system 100 is part of a UPS device, the processor 112 can be a microprocessor, such as a digital signal processor (DSP) of the UPS device (which makes measurements of current and voltage to control the UPS and communications from the UPS). The spectral analysis can be performed at the DSP, which is typically powerful enough to perform the requisite spectral analysis locally, particularly when a small sample of acoustic emissions 108a (i.e. of less than or equal to 1 second) is sensed by the sensor 110, since a small sample set makes the subsequent calculations computationally easier and cheaper. Alternatively, a new, separate, board can be added to the UPS device to perform the analysis. This board advantageously has wireless communication capabilities (for example, Bluetooth) to communicate with the processor of the UPS device and/or to receive the acoustic data 108b from the sensor 110. Moreover, a microphone or other suitable sensor for detecting acoustic emissions can be retrofitted to a UPS device to enable particle filter cleanliness to be determined. Alternatively, sensor 110 can be integrated into new UPS device designs.

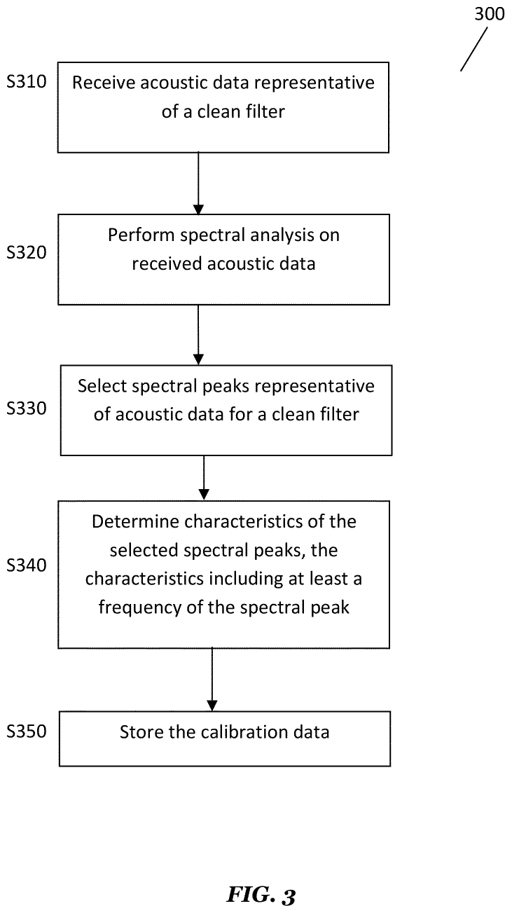

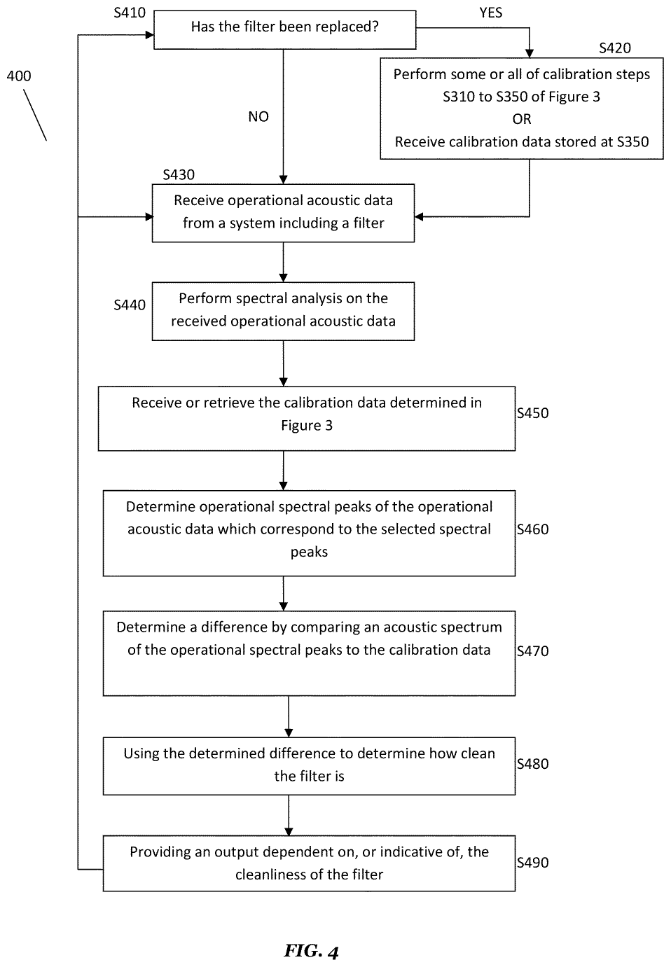

A method for detecting particle filter cleanliness is described with reference to FIGS. 3 and 4. FIG. 3 outlines the steps for a method 300 of calibrating for a clean particle filter 104 in system 100, in order to ascertain the acoustic spectrum, for example the base spectral peaks, indicative of a clean filter. FIG. 4 outlines an exemplary method 400 of detecting filter cleanliness, optionally in which said base spectral peaks are used to determine a frequency shift of the operational spectral peaks relative to the base spectral peaks. Methods 300 and 400 can be performed by processor 112 of system 100 upon execution, by the processor 112, of the instructions 118 stored in memory 116. In this example, system 100 is a system for cooling an electrical device and methods 300 and 400 utilise said system. However, system 100 is also suitable for use in applications other than cooling, and methods 300 and 400 can similarly be performed in such alternative applications. Similarly, method 300 can be performed independently of system 100, i.e. within a factory setting rather than within the operational environment of the particle filter.

At step 310 of calibration process 300 of FIG. 3, acoustic data representative of a clean filter is received. This data is the above described base acoustic data. The acoustic data is received from sensor 110 located in system 100, or alternatively, can be received from another sensor, for example when the calibration is performed in the factory rather than within the operational environment of the sensor. As discussed above, in order to reduce processing costs and make the spectral analysis easier, the received acoustic data is advantageously data which has been recorded or otherwise sensed by sensor no over a period of a few seconds only, more advantageously over a period of less than 1 second. Optionally, sensor 110 can be activated for a longer period of time, i.e. tens of seconds, or longer as required. Optionally, the acoustic data can be filtered to reduce or remove extraneous high or low frequency noise from other components of the system, as described above.

At step 320, spectral analysis is performed on the received acoustic data. As described above with reference to FIGS. 2A and 2B, in some examples spectral analysis can enable spectral peaks representative of the dominant frequencies within the acoustic data to be identified. For example, spectral peaks 220, 230, 240, 250 and 260 of FIG. 2A can be identified. Alternatively, the spectral analysis can comprise receiving acoustic data from the sensor, the acoustic data representative of a clean particle filter (or in some examples a dirty particle filter) and, more generally, deriving an acoustic spectrum from the acoustic data.

At step 330, which is an optional step, depending on the type of spectral analysis being performed, spectral peaks which best represent the received audio data are selected from the spectral analysis, i.e. spectral peaks 230, 240 and 250 (these selected peaks are the above described base spectral peaks). A single spectral peak may be selected, or more than one spectral peak may be selected. At step 340, again optionally, the characteristics of the selected spectral peaks are determined. The characteristics include, but are not limited to, the frequency of the selected spectral peaks. Another characteristic that may be used in determining a measure of cleanliness of a particle filter, in addition to the frequency, is the amplitude of the spectral peaks. Other suitable characteristics may be used instead of, or as well as, the amplitude.

At step 350, calibration data is stored. The calibration data can be data which represents the acoustic data, for example which represents the acoustic spectrum derived from the acoustic data. Alternatively, the calibration data can comprise the determined characteristics of the selected peaks. The characteristics may be stored in the form of a look up table, or in any other suitable format. The determined characteristics may be stored locally within the memory 114 associated with processor 112, or may be stored remotely on a server.

Performing steps 310 to 350 of calibration process 300 can enable calibration data (for example base spectral peaks, representative of noise from system 100 comprising a clean particle filter) to be determined. This calibration data, and/or calibration process, can then be used in the methods for detecting particle filter cleanliness described with reference to FIGS. 4 and 5. In some embodiments both method 300 and methods 400 and 500 are performed using the same system, in order that the initial calibration described with reference to FIG. 3 is specific to the operational system. In other embodiments, the calibration process is performed independently of the methods in FIGS. 4 and 5.

Calibration process 300 of FIG. 3 can be initiated in dependence on step S410, where it is determined whether a filter has been replaced. This initiation can be upon request of a user after a new, clean, particle filter 104 is placed in system 100. Alternatively, the calibration can be initiated automatically, based on an automatic determination that particle filter 104 has been replaced. If it is determined that the particle filter has been replaced, calibration occurs at S420. This calibration may require that calibration process 300 is performed at S420 to calibrate the new filter, or that the calibration data previously stored at step S350 is received.

In some arrangements, the received calibration data may be used without modification. However, optionally, when a new, clean, particle filter is placed in system 100, there may be a specific range of frequencies of base acoustic emissions which are expected. If the base spectral peaks determined at step S420 fall outside of these expected frequencies, this may indicate that the filter is dirty (i.e. not clean), in which case the characteristics determined at step S340 may not be stored; instead the characteristics of the base spectral peaks from a previous calibration step may be used in the rest of method 400. However, if it is confirmed that that the filter is clean, the mapping function(s) used at step S480 to determine a measure of cleanliness of the particle filter may be updated to reflect the frequency characteristics of the base spectral peaks associated with the new filter.

At step S430, operational acoustic data is received from sensor no of system 100. As discussed above, this data is representative of noise (or acoustic emissions) from system too due to the components of the system and the flow of fluid 102 through said components. In the operational state, the particle filter 104 may be clean, or may be dirty (at least partially clogged) with particles filtered from the fluid which obstruct the flow of fluid 102. Optionally, the operational acoustic data can be filtered to reduce or remove extraneous high or low frequency noise from other components of the system, as described above.

At step S440, spectral analysis is performed on the received operational acoustic data. As discussed, this spectral analysis may comprise deriving an acoustic spectrum for the operational acoustic data, to be compared to the acoustic spectrum represented by the calibration data received at step S420. Optionally, in some examples, as described with reference to step S460, the operational spectral peaks which correspond to the base spectral peaks selected at step S330 may be determined. Depending on the number of base spectral peaks selected, there may be one or more operational spectral peaks determined at step S460.

At step S450, the stored calibration data (for example, the characteristics of the base spectral peaks) are optionally retrieved or otherwise received. It will be understood that where the calibration data was already retrieved at step S420, it may not be again retrieved at S450. As discussed above, the calibration data can be stored locally to the processor 112 in memory 114, or remotely on a server. The calibration data can be stored in a look up table, or in any other suitable format. Step S450 can occur at any suitable point in method 400, for example, it will be understood that step S450 can occur before step S430.

At step S470, at least part of the acoustic spectrum derived from the operational acoustic data is compared to a corresponding part of the acoustic spectrum represented by the calibration data. For example, the characteristics of the selected spectral peaks, or base spectral peaks, including the frequency of the base spectral peaks, may be compared to a frequency of the operational spectral peaks determined at step S460. Alternatively, the comparison may employ cross-correlation, for example. Through this comparison, a difference between the acoustic spectrum and the second acoustic spectrum is determined. In some examples, this difference may be a frequency and/or amplitude shift of the operational spectral peaks relative to the base spectral peaks.

An example method of comparison may require some or all of the following steps:

1. Defining a set of “previous peaks”, which in the first iteration are equal to the “clean filter peaks from calibration”—in other words, these previous peaks can be considered calibration data during the initial method steps.

2. Collecting operational acoustic data.

3. Deriving or creating an acoustic spectrum from the operational acoustic data.

4. Searching through all peaks of the acoustic spectrum with a specific frequency range and/or with a specific amplitude. For example, searching for peaks with a frequency of between 4001200 Hz and a normalized amplitude of greater than 0.1 (the amplitude could alternatively be found by considering the measured voltages of the operational acoustic data). This provides a subset of operational data for comparison. Depending on the application, difference frequency and/or amplitude ranges could be employed.

5. Determining whether the subset contains peaks that are located within a predetermined frequency range of the previous peaks. For example, does the subset contain peaks which have a frequency within a range of (frequency of the previous peaks ±ioHz)?
No Initiate filter warning or alarm—i.e. the difference exceeds a certain threshold.
Yes Replace parameters in “previous peaks” with parameters of those peaks we just found.

6: Do the new “previous peaks” differ by more than a predetermined threshold from the initial calibration data, i.e. the “clean filter peaks from calibration”?
No Jump back to step 2 and repeat process.
Yes Initiate filter warning or alarm—i.e. the difference exceeds a certain threshold.

In this exemplary method, the process must be repeated relatively regularly, i.e. once per day, in order to track the changes in the spectral peaks. Alternatively, any other suitable method for comparing the acoustic spectra and determining a difference can be employed. The difference at step S470 of FIG. 4 can include one, or both, of the determined differences described above (i.e. the difference at step 5 and/or the difference at step 6).

Optionally, at step S490, the difference, such as the frequency shift, is used to determine how clean the particle filter 104 is. A mapping function, such as a calibration curve or a look up table, may be used to map the determined frequency shift to a corresponding measure of cleanliness of the filter. Optionally, environmental parameters are also measured during method 400, such as ambient temperature and relative humidity, and these environmental parameters may be taken into account in the mapping function; for example, a different mapping function may be used depending on the measured environmental parameters, or adjustments may be applied to the mapping function to compensate for the measured environmental parameters.

Optionally, a predetermined threshold, or limit, of particle filter dirtiness is defined within the mapping function. The determined difference (such as the frequency and/or amplitude shift) can be matched against the mapping function to determine whether the shift is indicative of the filter being 10% towards the predetermined threshold, 50% towards the predetermined threshold, 70% towards the predetermined threshold, etc. Advantageously, the threshold occurs before the absolute limit of particle filter dirtiness, i.e. before the filter is completely clogged, in order to help ensure that some degree of electrical device cooling can occur before the particle filter is cleaned or changed. Alternatively, any other suitable measure of cleanliness can be used.

At step S490, an output is provided based on the difference determined at step S470. In some examples, the output can be dependent on, or indicative of, the cleanliness of the filter. For example, a warning output or signal such as an alarm or an automated message may be provided. The output may indicate the particle filter 104 is 90% towards the predetermined threshold. This type of warning, which advantageously is issued before the particle filter is completely clogged with particles, can facilitate preventative servicing of the particle filter 104, which can in turn enable the lifetime of the electrical device to be prolonged. Alternatively, the output can simply be an alarm output, for example. The alarm may indicate a filter fault, or be a warning that the acoustic spectra varies by a predetermined amount from the spectra of a clean filter, for example.

In some examples, the remaining lifetime of the particle filter is estimated and provided as an output. For example, a filter which is deemed to be 50% towards the predetermined threshold, or limit, of particle filter dirtiness may only have a third of its lifetime remaining due to the adverse effects of particle accumulation.

Different outputs may be provided at different differences, or at different thresholds of filter cleanliness. The threshold at which an output is provided can vary depending on many factors—the location of the electrical device and system (i.e. how remote it is, how difficult it is to schedule a service) and the environmental parameters (where these are measured or sensed). For example, the ambient temperature can be relevant to how critical failure of the particle filter is, so the threshold for issuing an output, such as a warning alarm regarding the cleanliness of the filter or the remaining lifetime, may be lower when the ambient temperature is higher. Alternatively, a high ambient temperature can be indicative of a failing in the cooling system, and so thresholds may be adjusted to reduce the estimated remaining lifetime of the particle filter based on the detected ambient temperature, for example.

After step S490, the method can return to step S340 or step S410, depending on the particular implementation; in other words, the monitoring of particle filter cleanliness can be continuous.

The above-described method for detecting, or monitoring, particle filter cleanliness can provide a robust approach which can obviate many of the issues associated with other, known, approaches, namely the complexity and expense of the monitoring system itself and the computational cost of subsequent data analysis. By considering at least part of the acoustic spectra, for example only certain spectral peaks from the acoustic data, the complexity of the analysis underlying the method can be reduced, thereby facilitating a reduction in computational load and computing expense. By correlating or otherwise mapping the difference in the spectra, such as a frequency and/or amplitude shift of selected spectral peaks, to a measure of filter cleanliness, a simple and effective output indicating the state filter can be provided. These advantages allow the above-described method to be implemented in remote and/or portable devices, and can thereby reduce servicing costs and improve the lifetime of electrical devices in which the method is employed.

It is noted herein that while the above describes various examples, these descriptions should not be viewed in a limiting sense. Rather, there are several variations and modifications which may be made without departing from the scope of the present invention as defined in the appended claims.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A method of detecting particle filter cleanliness, the method comprising:
receiving calibration data for a particle filter, the calibration data representing an acoustic spectrum;
receiving operational acoustic data from a sensor located in a system comprising a fan and the particle filter;
deriving a second acoustic spectrum from the operational acoustic data;
comparing at least part of the acoustic spectrum with a corresponding part of the second acoustic spectrum;
determining a frequency shift between the acoustic spectrum and the second acoustic spectrum based on the comparing; and
providing an output based on the frequency shift.

2. The method of claim 1, further comprising:
using the frequency shift to determine a measure of cleanliness of the particle filter.

3. The method of claim 2, wherein using the frequency shift comprises correlating the frequency shift with the measure of cleanliness of the particle filter based on a correlation function and/or a mapping function.

4. The method of claim 1, wherein comparing comprises:
performing spectral analysis on the acoustic spectrum to determine one or more spectral peaks representative of the calibration data;
performing spectral analysis on the second acoustic spectrum to determine one or more operational spectral peaks, representative of the operational acoustic data, which correspond to the one or more spectral peaks;
comparing the one or more spectral peaks to the one or more corresponding operational spectral peaks,
wherein determining the frequency shift between the acoustic spectrum and the second acoustic spectrum based on the comparing comprises determining a frequency shift of the one or more operational spectral peaks relative to the one or more spectral peaks.

5. (canceled)

6. (canceled)

7. The method of claim 1, further comprising calibrating the system, wherein calibrating the system comprises:
receiving base acoustic data from the sensor, the base acoustic data representative of a clean particle filter; and
deriving the acoustic spectrum from the base acoustic data.

8. The method of claim 7, further comprising:
detecting, as a first step, that the particle filter has been changed;
after deriving the acoustic spectrum from the base acoustic data, determining whether the particle filter is clean based on comparing the acoustic spectrum to an acoustic spectrum expected for the clean particle filter; and
based on the particle filter being clean, modifying the calibration data based on the acoustic spectrum.

9. The method of claim 1, further comprising measuring one or more environmental parameters, wherein the environmental parameters comprise at least one of: ambient temperature, relative humidity and air pressure.

10. The method of claim 9, wherein the output is based on the frequency shift and the one or more measured environmental parameters.

11. The method of claim 1, wherein providing the output comprises automatically sending an alert signal abased on the frequency shift exceeding a predetermined threshold.

12. The method of claim 11, further comprising measuring one or more environmental parameters, wherein the environmental parameters comprise at least one of: ambient temperature, relative humidity and air pressure, and wherein the predetermined threshold is dependent on the one or more measured environmental parameters.

13. The method of claim 1, further comprising filtering out the operational acoustic data outside of a predetermined frequency range before determining the frequency shift between the acoustic spectrum and the second acoustic spectrum.

14. The method of claim 1, wherein receiving the operational acoustic data comprises periodically receiving the operational acoustic data at a rate of at least once per month.

15. (canceled)

16. (canceled)

17. (canceled)

18. (canceled)

19. (canceled)

20. (canceled)

21. (canceled)

22. (canceled)

23. An apparatus comprising:
a sensor for sensing acoustic emissions, wherein the sensor is located in a system comprising a fan and a particle filter; and
a processor for receiving, from the sensor, acoustic data representation of the acoustic emissions, wherein the processor is configured to:
receive calibration data for the particle filter, the calibration data representing an acoustic spectrum;
receive operational acoustic data from the sensor;
derive a second acoustic spectrum from the operational acoustic data;
compare at least part of the acoustic spectrum with a corresponding part of the second acoustic spectrum;
determine a frequency shift between the acoustic spectrum and the second acoustic spectrum based on the comparing; and
provide an output based on the frequency shift.

24. The apparatus of claim 23, wherein the apparatus further comprises the fan and the particle filter, wherein the apparatus is configured to cool an electrical device.

25. An uninterruptible supply device comprising the apparatus of claim 23.

26. The method of claim 7, wherein calibrating the system further comprises storing the calibration data representing the acoustic spectrum.
